(19) United States
(12) Patent Application Publication
(10) Pub. No.: US 2025/0221253 A1
(43) Pub. Date: Jul. 3, 2025

(54) DISPLAY DEVICE

(71) Applicant: LG DISPLAY CO., LTD., Seoul (KR)

(72) Inventor: Jinseon PARK, Seoul (KR)

(73) Assignee: LG DISPLAY CO., LTD., Seoul (KR)

(21) Appl. No.: 18/746,746

(22) Filed: Jun. 18, 2024

(30) Foreign Application Priority Data
Dec. 28, 2023 (KR) 10-2023-0195533

(51) Int. Cl. H10K 59/80

(52) U.S. Cl. CPC H10K 59/8723; H10K 59/8722; H10K 59/873

(57) ABSTRACT

A display device includes a substrate including a display area, and a non-display area configured to surround the display area, an encapsulation substrate including a base portion disposed to be opposite to the substrate, and a protruding portion protruding from the base portion toward the substrate and disposed in the non-display area and a bonding layer disposed between the substrate and the encapsulation substrate and disposed in an area excluding an area in which the protruding portion is disposed, thereby minimizing or reducing the moisture penetration through the side surface of the display device.

### CROSS-REFERENCE TO RELATED APPLICATION

This application claims the priority of Korean Patent Application No. 10-2023-0195533 filed on Dec. 28, 2023, which is hereby incorporated herein by reference in its entirety.

### BACKGROUND

### Field of the Disclosure

The present specification relates to a display device, and more particularly, to a display device in which lateral moisture penetration is minimized or reduced.

### Description of the Background

Display devices, which display a variety of information on a screen, are a key technology in the information and communication age. Display devices are evolving to become thinner, lighter, and more portable, and have higher performance. Therefore, organic light-emitting display (OLED) devices, which display images by controlling the amount of light emitted from organic light-emitting layers, are in the limelight.

The organic light-emitting display device is a spontaneous light-emitting element using a thin light-emitting layer between electrodes and has an advantage of being implemented as a thin-film display device. A general organic light-emitting display device has a structure in which a pixel drive circuit and an organic light-emitting element are formed on a substrate, and light emitted from the organic light-emitting element passes through the substrate or a barrier layer, such that images are displayed.

The organic light-emitting element is easily degraded by internal factors, such as degradation of the electrode and the light-emitting layer caused by oxygen or degradation caused by a reaction between the light-emitting layer and an interface. Further, the organic light-emitting element is easily degraded by external factors such as outside moisture, oxygen, ultraviolet rays, and manufacturing conditions of the elements. In particular, because outside oxygen and moisture have significant effects on the lifespan of the element, a technology for encapsulating organic light-emitting display devices is very important.

### SUMMARY

Accordingly, the present disclosure is directed to a display device that substantially obviates one or more of problems due to limitations and disadvantages described above.

More specifically, the present specification is to provide a display device in which lateral moisture penetration is minimized or reduced.

The present specification is also to provide a display device capable of implementing a narrow bezel.

Further, the present specification is to provide a display device with improved reliability and display quality.

The present disclosure is not limited to the above-mentioned, and other features, which are not mentioned above, may be clearly understood by those skilled in the art from the following descriptions.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display device includes: a substrate including a display area, and a non-display area configured to surround the display area, an encapsulation substrate including a base portion disposed to be opposite to the substrate, and a protruding portion protruding from the base portion toward the substrate and disposed in the non-display area and a bonding layer disposed between the substrate and the encapsulation substrate and disposed in an area excluding an area in which the protruding portion is disposed to minimize or reduce the moisture penetration through the side surface of the display device.

Other detailed matters of the exemplary aspects are included in the detailed description and the drawings.

According to the aspect of the present specification, the encapsulation substrate includes the protruding portion disposed in the non-display area, which may minimize or reduce the moisture penetration through the side surface of the display device.

According to the aspect of the present specification, the spacer having the groove structure is disposed on the substrate, which may mitigate an impact that occurs during the process of joining the encapsulation part and the substrate.

According to the aspect of the present specification, the reliability and display quality may be improved.

The effects according to the present disclosure are not limited to the contents exemplified above, and more various effects are included in the present specification, and it is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a schematic top plan view of a display device according to an aspect of the present specification;

FIG. 2 is a cross-sectional view illustrating a subpixel of the display device according to the aspect of the present specification;

FIG. 3 is a rear view of an encapsulation part of the display device according to the aspect of the present specification;

FIG. 4 is a top plan view illustrating a substrate and a spacer of the display device according to the aspect of the present specification;

FIG. 5 is a view schematically illustrating a process of joining the encapsulation part and the substrate of the display device according to the aspect of the present specification;

FIG. 6 is a schematic cross-sectional view according to the aspect of the present specification; and

FIG. 7 is a schematic cross-sectional view according to another aspect of the present specification.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art may fully understand the disclosures of the present disclosure and the scope of the present disclosure.

The shapes, sizes, ratios, angles, numbers, and the like illustrated in the accompanying drawings for describing the exemplary aspects of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various aspects of the present disclosure may be partially or entirely adhered to or combined with each other and may be interlocked and operated in technically various ways, and the aspects may be carried out independently of or in association with each other.

Hereinafter, a display device according to exemplary aspects of the present disclosure will be described in detail with reference to accompanying drawings.

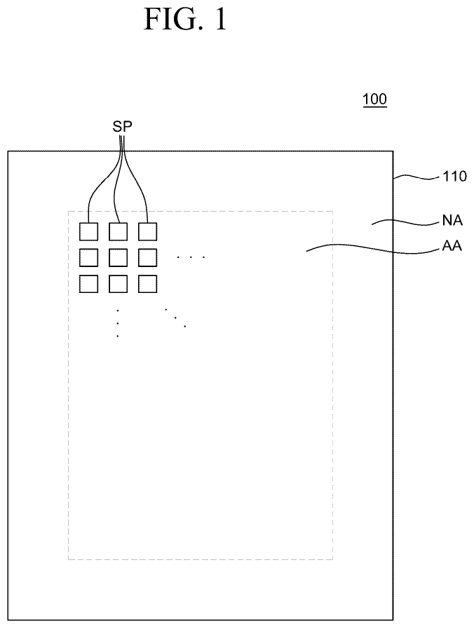

FIG. 1 is a schematic top plan view of a display device according to an aspect of the present specification.

With reference to FIG. 1, a display device 100 may include a display area AA, and a non-display area NA configured to be adjacent to the display area AA or to partially or fully surround the display area AA.

The display area AA is an area of the display device 100 in which images are displayed. The display area AA may include a plurality of subpixels SP constituting a plurality of pixels, and a circuit configured to operate the plurality of subpixels SP. The plurality of subpixels SP is minimum units that constitute the display area AA. As an example, n subpixels SP may constitute a single pixel, where n may be a natural number lager than 1. A light-emitting element, a thin-film transistor for operating the light-emitting element, and the like may be disposed in each of the plurality of subpixels SP. The plurality of light emitting elements may be differently defined depending on the type of display panel. For example, in case that the display panel is an organic light-emitting display panel, the light-emitting element may be an organic light-emitting diode (OLED). As an example, in case that the display panel is a micro-LED display panel, the light-emitting element may be a micro-LED. Embodiments are not limited thereto.

A plurality of lines for transmitting various types of signals to the plurality of subpixels SP may be disposed in the display area AA. For example, the plurality of lines may include a plurality of data lines for supplying data voltages to the plurality of subpixels SP, and a plurality of scan lines for supplying scan signals to the plurality of subpixels SP. The plurality of scan lines may extend in one direction in the display area AA and be connected to the plurality of subpixels SP. The plurality of data lines may extend in a direction different from one direction in the display area AA and be connected to the plurality of subpixels SP. In addition, a low-potential power line, a high-potential power line, a reference line, a sensing line, and the like may be further disposed in the display area AA. However, the present specification is not limited thereto.

The non-display area NA may be defined as an area in which no image is displayed, i.e., an area extending from the display area AA. The non-display area NA may include link lines and pad electrodes for transmitting signals to the subpixels SP in the display area AA. Alternatively, the non-display area NA may include drive ICs such as gate drivers IC and data drivers IC.

However, as an example, the non-display area NA may be positioned on a rear surface of the display panel, i.e., a surface on which the subpixel SP is not present. As an example, the non-display area NA may be at least partially positioned on a rear surface of the display panel, by being bent from the display area AA, without being limited thereto. Alternatively, the non-display area NA may be excluded. However, the present specification is not limited to the configuration illustrated in the drawings.

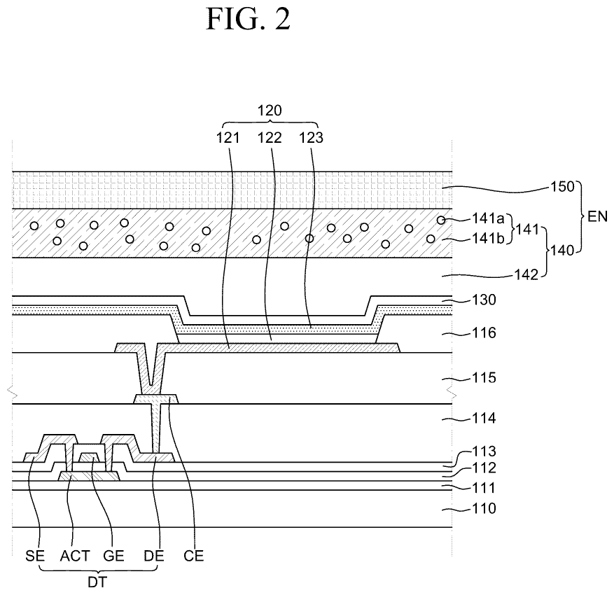

FIG. 2 is a cross-sectional view illustrating the subpixel of the display device according to the aspect of the present specification. Specifically, FIG. 2 is a cross-sectional view illustrating one subpixel SP of the display device 100 according to the aspect of the present specification.

With reference to FIG. 2, a substrate 110 may be a substrate, i.e., an insulation substrate that supports constituent elements disposed above the display device. The substrate 110 may be made of glass, resin, ceramics, metal foil or the like. In addition, the substrate 110 may be made of a material including polymer or plastic. As an example, the substrate 110 may be a rigid substrate or a flexible substrate. As an example, the substrate 110 may be a transparent substrate or an opaque substrate. As an example, the substrate 110 may be formed by a single layer or multilayer of the same material or different materials. However, the present specification is not limited thereto.

A buffer layer 111 may be disposed on the substrate 110. The buffer layer 111 may reduce the penetration of moisture or impurities through the substrate 110. For example, the buffer layer 111 may be configured as a single layer or multilayer made of silicon oxide (SiOx) or silicon nitride (SiNx). However, the present specification is not limited thereto. As an example, the buffer layer 111 may be excluded in accordance with the type of the substrate 110 or the type of transistor DT. However, the present specification is not limited thereto.

The transistor DT including an active layer ACT, a gate electrode GE, a source electrode SE, and a drain electrode DE may be disposed on the buffer layer 111.

First, the active layer ACT of the transistor DT may be disposed on the buffer layer 111. The active layer ACT may be made of a semiconductor material such as an oxide semiconductor, amorphous silicon, polysilicon, compound semiconductor, or organic semiconductor, etc. However, the present specification is not limited thereto. In addition, although not illustrated in the drawings, in addition to the transistor DT, other transistors, such as a switching transistor, a sensing transistor, and/or a light emission control transistor, may be additionally disposed. The active layers of these transistors may be made of a semiconductor material such as an oxide semiconductor, amorphous silicon, rpolysilicon, compound semiconductor, or organic semiconductor, etc. However, the present specification is not limited thereto. In addition, the active layers of the transistors, such as the transistor DT, the switching transistor, the sensing transistor, and the light emission control transistor, which are included in pixel circuits, may be made of the same material or different materials.

A gate insulation layer 112 may be disposed on the active layer ACT. The gate insulation layer 112 may be an insulation layer for electrically insulating the active layer ACT and the gate electrode GE. The gate insulation layer 112 may be configured as a single layer or multilayer made of silicon oxide (SiOx) or silicon nitride (SiNx). However, the present specification is not limited thereto.

The gate electrode GE may be disposed on the gate insulation layer 112. The gate electrode GE may be made of an electrically conductive material, for example, copper (Cu), aluminum (Al), molybdenum (Mo), nickel (Ni), titanium (Ti), chromium (Cr), or an alloy thereof. However, the present specification is not limited thereto.

An interlayer insulation layer 113 may be disposed on the gate electrode GE. Contact holes, through which the source electrode SE and the drain electrode DE are connected to the active layer ACT, may be formed in the interlayer insulation layer 113. The interlayer insulation layer 113 may be an insulation layer for protecting components disposed below the interlayer insulation layer 113. The interlayer insulation layer 113 may be configured as a single layer or multilayer made of silicon oxide (SiOx) or silicon nitride (SiNx). However, the present specification is not limited thereto.

The source electrode SE and the drain electrode DE, which are electrically connected to the active layer ACT, may be disposed on the interlayer insulation layer 113. The drain electrode DE may be connected to a first electrode 121 of a light-emitting element 120. As an example, the drain electrode DE may be connected to the first electrode 121 of the light-emitting element 120 through a connection electrode CE, without being limited thereto. As an example, the connection electrode CE may be omitted, and the drain electrode DE may be directly connected to the first electrode 121 of the light-emitting element 120. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present specification is not limited thereto.

A first planarization layer 114 may be disposed on the source electrode SE and the drain electrode DE. The first planarization layer 114 may planarize an upper portion of the pixel circuit including the transistor DT. The first planarization layer 114 may be configured as a single layer or multilayer and made of benzocyclobutene (BCB) or an acrylic-based organic material, for example. However, the present specification is not limited thereto. Meanwhile, a contact hole, through which the drain electrode DE is connected to the first electrode 121 of the light-emitting element 120 or the connection electrode CE, may be formed in the first planarization layer 114.

The connection electrode CE may be disposed on the first planarization layer 114. The connection electrode CE may electrically connect the drain electrode DE and the first electrode 121 of the light-emitting element 120 through the contact hole formed in the first planarization layer 114.

A second planarization layer 115 may be disposed on the first planarization layer 114 and the connection electrode CE. Like the first planarization layer 114, the second planarization layer 115 may planarize the upper portion of the pixel circuit including the transistor DT. The second planarization layer 115 may be configured as a single layer or multilayer and made of benzocyclobutene (BCB) or an acrylic-based organic material, for example. However, the present specification is not limited thereto.

The light-emitting element 120 may be disposed on the second planarization layer 115. The light-emitting element 120 may include the first electrode 121, a light-emitting layer 122, and a second electrode 123 that are sequentially stacked.

The first electrode 121 may be disposed on the second planarization layer 115. The first electrode 121 may be a layer, i.e., an anode for supplying positive holes to the light-emitting layer 122. In this case, because the first electrode 121 is a layer for supplying positive holes to the light-emitting layer 122, as an example, the first electrode 121 may be made of an electrically conductive material having a high work function, without being limited thereto. The first electrode 121 may be made of an electrically conductive material, for example, a transparent conductive material such as indium tin oxide (ITO) and indium zinc oxide (IZO) or an opaque conductive material such as titanium (Ti), gold (Au), silver (Ag), copper (Cu), or an alloy thereof. However, the present specification is not limited thereto.

A bank 116 may be disposed on the first electrode 121 and the second planarization layer 115. As an example, the bank 116 may cover an edge of the first electrode 121 of the light-emitting element 120 and define a light-emitting area. That is, the bank 116 may separate the plurality of subpixels SP. The present specification is not limited thereto. As an example, the bank 116 may not cover the edge of the first electrode 121, and may be in contact with the edge of the first electrode 121, without being limited thereto. As an example, the bank 116 may be made of an insulating material to insulate the first electrodes 121 of the adjacent subpixels SP. In addition, as an example, the bank 116 may be configured as a black bank with a high optical absorption rate or a high reflectivity to suppress a color mixture between the adjacent subpixels SP. For example, the bank 116 may be made of polyimide resin, acrylic resin, or benzocyclobutene (BCB) resin. However, the present specification is not limited thereto. As an example, the bank 116 may also be formed of a transparent material or a semi-transparent material, without being limited thereto.

The light-emitting layer 122 may be disposed on the first electrode 121. The light-emitting layer 122 is a layer that emits light by combining electrons and positive holes.

As an example, the light-emitting element 120 may further include a hole injection layer, a hole transport layer, an electron transport layer, an electron injection layer, and the like to improve luminous efficiency of the light-emitting element 120. For example, the hole injection layer and the hole transport layer may be disposed between the first electrode 121 and the light-emitting layer 122, and the electron transport layer and the electron injection layer may be disposed between the light-emitting layer 122 and the second electrode 123. In addition, as an example, a hole blocking layer or an electron blocking layer may be disposed on the light-emitting layer 122 to further improve the efficiency in recombining positive holes and electrons. The present specification is not limited thereto. As an example, at least one of the hole injection layer, the hole transport layer, the electron transport layer, the electron injection layer, the hole blocking layer and the electron blocking layer may be omitted.

The second electrode 123 may be disposed on the light-emitting layer 122. The second electrode 123 may be a layer, i.e., a cathode for smoothly supplying electrons to the light-emitting layer 122. Therefore, as an example, the second electrode 123 may be made of a metallic material with a low work function, without being limited thereto. For example, the second electrode 123 may be made of a metallic material selected from calcium (Ca), barium (Ba), aluminum (Al), silver (Ag), and an alloy containing one or more of the above-mentioned elements. However, the present specification is not limited thereto.

A protective layer 130 may be disposed on the light-emitting element 120. The protective layer 130 may protect the light-emitting element 120 from outside oxygen, moisture, or the like. The protective layer 130 may be made of one or more materials selected from a group consisting of various inorganic insulating materials, for example, silicon nitride (SiNx), silicon oxide (SiOx), aluminum oxide (AlOx), and silicon oxynitride (SiON). However, the present specification is not limited thereto. As an example, the protective layer 130 may be omitted according to the design.

An encapsulation part EN may be disposed on the protective layer 130. As an example, the encapsulation part EN may include a bonding layer 140 and an encapsulation substrate 150, without being limited thereto.

First, the bonding layer 140 may be disposed on the protective layer 130. The bonding layer 140 may be disposed between the encapsulation substrate 150 and the substrate 110 on which the transistor DT and the light-emitting element 120 are disposed. The bonding layer 140, together with the encapsulation substrate 150, may protect the light-emitting element 120 from outside moisture, oxygen, or the like. Meanwhile, as an example, the bonding layer 140 may be applied onto the encapsulation substrate 150 first and then disposed to be opposite to the substrate 110, thereby fixing the substrate 110 and the encapsulation substrate 150. For example, the bonding layer 140 may be a face seal adhesive (FSA) configured as a multilayer. However, the present specification is not limited thereto. As another example, the bonding layer 140 may be applied onto the protective layer 130 first and then the encapsulation substrate 150 is disposed to be opposite to the substrate 110, thereby fixing the substrate 110 and the encapsulation substrate 150, without being limited thereto.

With reference to FIG. 2, as an example, the bonding layer 140 may include a first bonding layer 141 and a second bonding layer 142. The present specification is not limited thereto. As an example, the bonding layer 140 may include a single bonding layer or more than two bonding layers.

The first bonding layer 141 may be joined to one surface of the encapsulation substrate 150. For example, the first bonding layer 141 may adjoin a bottom surface of the encapsulation substrate 150. The first bonding layer 141 may include a curable resin 141b and moisture adsorbents 141a dispersed in the curable resin 141b. The moisture adsorbents 141a of the first bonding layer 141 may use physical or chemical reactions and the like and absorb or remove moisture or oxygen introduced from the outside. For example, the curable resin 141b may be made of a polymer material such as an epoxy-based material or an olefin-based material. However, the present specification is not limited thereto. The first bonding layer 141b may also be referred to as a barrier layer (B-layer).

The second bonding layer 142 may be disposed below the first bonding layer 141 and joined to the substrate 110 on which the light-emitting element 120 is disposed. Specifically, as described below, the second bonding layer 142 may be joined to side surfaces of protruding portions 150b of the encapsulation substrate 150. For example, the second bonding layer 142 may be made of a thermosetting resin or a photocurable resin. However, the present specification is not limited thereto. The second bonding layer 142 may also be referred to as a transparent layer (T-layer).

The encapsulation substrate 150 may be disposed on the bonding layer 140. The encapsulation substrate 150 may be disposed to be opposite to the substrate 110 and protect the light-emitting element, together with the bonding layer 140, from outside moisture, oxygen, or the like. For example, the encapsulation substrate 150 may be made of a material such as glass, plastic, or metal, without being limited thereto. The material of the encapsulation substrate 150 may be determined depending on a light-emitting direction of the display device 100. As an example, The display device 100 according to the aspect of the present specification may be a bottom emission type display device, and the encapsulation substrate 150 may be made of metal. However, the present specification is not limited thereto. As another example, the display device 100 according to the aspect of the present specification may be a top emission type display device or a dual emission type display device.

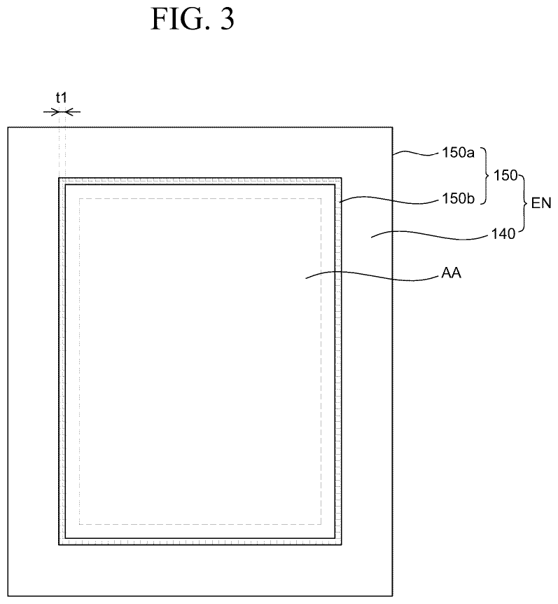

The encapsulation part EN will be described in detail with reference to FIGS. 3 to 6 to be described below.

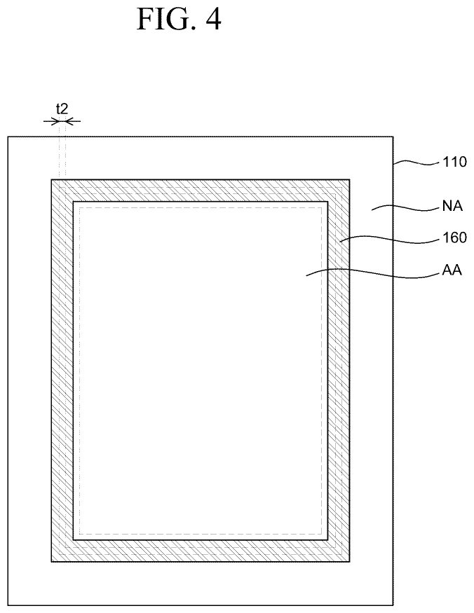

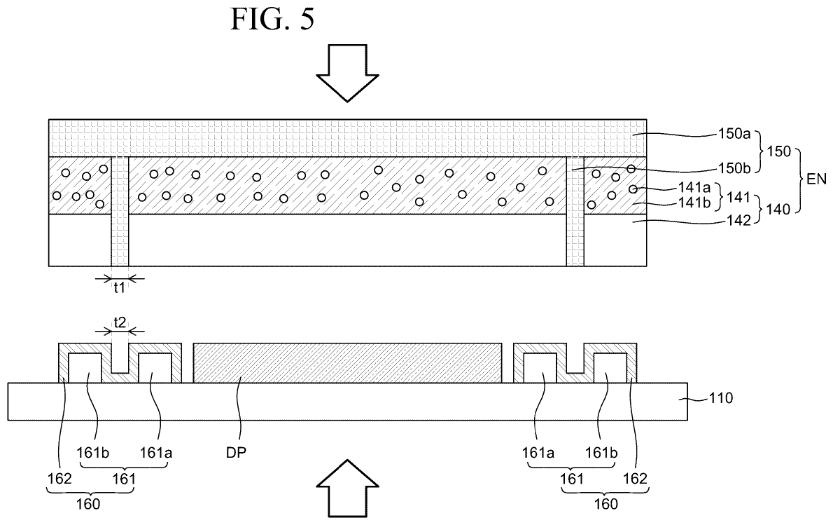

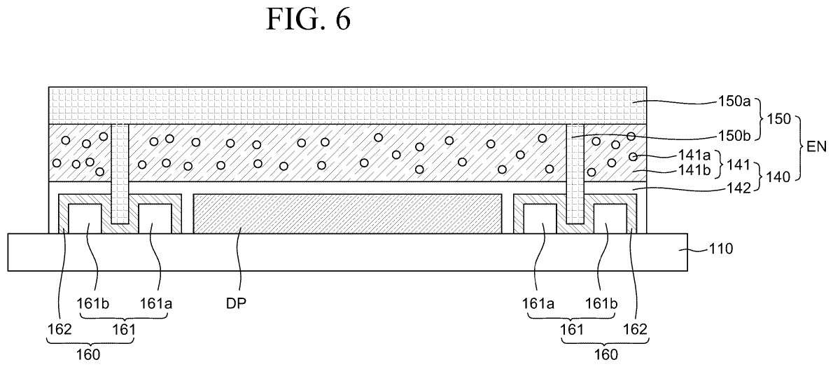

FIG. 3 is a rear view of the encapsulation part of the display device according to the aspect of the present specification. FIG. 4 is a top plan view illustrating the substrate and a spacer of the display device according to the aspect of the present specification. FIG. 5 is a view schematically illustrating a process of joining the encapsulation part and the substrate of the display device according to the aspect of the present specification. FIG. 6 is a schematic cross-sectional view according to the aspect of the present specification. Meanwhile, for convenience of description, FIGS. 5 and 6 illustrate a configuration, which is defined from an upper side of the substrate 110 to the protective layer 130, as a display part DP.

First, with reference to FIGS. 3, 5, and 6, the encapsulation part EN may include the bonding layer 140 and the encapsulation substrate 150.

The encapsulation substrate 150 may include a base portion 150a and the protruding portions 150b. The base portion 150a may be a portion disposed to be opposite to the substrate 110 and have a plate shape. The protruding portion 150b may have a shape extending from the base portion 150a and protruding toward the substrate 110. For example, the protruding portion 150b may be disposed to be substantially perpendicular to the substrate 110, without being limited thereto. As an example, the protruding portion 150b may be disposed to intersect with the substrate 110 at a certain angle. As an example, the protruding portion 150b may be disposed in the non-display area NA. As an example, the protruding portion 150b may protect the display device 100 from the penetration of outside moisture so that moisture, which is introduced from a side surface, does not penetrate into the display area AA. Meanwhile, as an example, after the encapsulation part EN and the substrate 110 are joined, an end of the protruding portion 150b of the encapsulation substrate 150 may be disposed in a groove of a spacer 160. That is, the protruding portion 150b of the encapsulation substrate 150 may be disposed to occupy the entire groove of the spacer 160. The present specification is not limited thereto. As an example, the protruding portion 150b of the encapsulation substrate 150 may be disposed to occupy at least a portion of the groove of the spacer 160. As an example, the protruding portion 150b of the encapsulation substrate 150 may be disposed to contact a bottom surface of the groove of the spacer 160. As an example, the protruding portion 150b of the encapsulation substrate 150 may be disposed to be spaced apart from the bottom surface of the groove of the spacer 160. As an example, the spacer 160 may have no groove. As an example, the protruding portion 150b of the encapsulation substrate 150 may be disposed to contact the spacer 160. As an example, the protruding portion 150b of the encapsulation substrate 150 may be disposed to contact the substrate 110. As an example, the protruding portion 150b of the encapsulation substrate 150 may be disposed to be spaced apart from the substrate 110 or the spacer 160. As an example, the protruding portion 150b of the encapsulation substrate 150 may be disposed to overlap at least a portion of the display part DP in a lateral direction. As an example, the protruding portion 150b of the encapsulation substrate 150 may be disposed to fully or partially surround the display area AA. The present specification is not limited thereto.

With reference to FIGS. 5 and 6, the first bonding layer 141 of the bonding layer 140 may adjoin a bottom surface of the base portion 150a of the encapsulation substrate 150 and adjoin the side surface of the protruding portion 150b of the encapsulation substrate 150. The second bonding layer 142 may be disposed below the first bonding layer 141 and adjoin the side surface of the protruding portion 150b of the encapsulation substrate 150.

With reference to FIGS. 4 to 6, the spacer 160 may be disposed on the substrate 110, without being limited thereto. The spacer 160 may protect the substrate 110 from an impact that may occur during a process of joining the encapsulation part EN and the substrate 110 on which the display part DP is disposed. That is, because the encapsulation substrate 150 includes the protruding portion 150b, the substrate 110 may be damaged as the substrate 110 is dented when the protruding portion 150b directly adjoins the substrate 110. Therefore, the spacer 160 may be disposed to correspond to an area in which the protruding portion 150b is disposed. As an example, the spacer 160 may be disposed in the non-display area NA. As an example, the spacer 160 may partially or fully surround the display area AA. As an example, the spacer 160 may be omitted according to the design.

In addition, as an example, the groove may be disposed in a top surface of the spacer 160. As an example, the end of the protruding portion 150b of the encapsulation substrate 150 is disposed in the groove of the spacer 160 without being disposed on the substrate 110, such that the spacer 160 may protect the substrate 110. Therefore, a width t2 of the groove of the spacer 160 may be equal to or larger than a width t1 of the protruding portion 150b of the encapsulation substrate 150.

With reference to FIGS. 5 and 6, as an example, the spacer 160 may include organic pattern 161 and a metal layer 162. The present specification is not limited thereto. As an example, the spacer 160 may be formed of any inorganic or organic materials as long as it could protect the substrate 110.

First, as an example, the organic pattern 161 may include a first organic pattern 161a and a second organic pattern 161b. The first organic pattern 161a may be disposed in the non-display area NA and disposed on the substrate 110 while partially or fully surrounding the display area AA. The second organic pattern 161b may be provided on the substrate 110, disposed outward of the first organic pattern 161a, and disposed to partially or fully surround the display area AA and the first organic pattern 161a. The first organic pattern 161a and the second organic pattern 161b may be disposed to be spaced apart from each other to define a groove. That is, the first organic pattern 161a and the second organic pattern 161b may be disposed so that the substrate 110 is exposed between the first organic pattern 161a and the second organic pattern 161b. The organic pattern 161 may be made of an organic insulating material instead of an inorganic insulating material to define the groove. For example, the organic pattern 161 may be made of the same material as the first planarization layer 114, the second planarization layer 115, or the bank 116. However, the present specification is not limited thereto. As an example, the organic pattern 161 may be also made of an inorganic insulating material.

Like the organic pattern 161, the metal layer 162 may be disposed in the non-display area NA while partially or fully surrounding the display area AA. Specifically, the metal layer 162 may be disposed on the first organic pattern 161a and the second organic pattern 161b to partially or fully cover a surface of the first organic pattern 161a and a surface of the second organic pattern 161b. Therefore, as an example, the metal layer 162 may be disposed between the first organic pattern 161a and the second organic pattern 161b and adjoin the substrate 110. Therefore, after the encapsulation part EN and the substrate 110 are joined, the end of the protruding portion 150b of the encapsulation substrate 150 may be disposed in the groove and adjoin the metal layer 162 instead of the substrate 110. The present specification is not limited thereto. As an example, there could be another organic or inorganic pattern between the metal layer 162 and the substrate 110, without being limited thereto. As an example, the end of the protruding portion 150b of the encapsulation substrate 150 may be disposed in the groove while not adjoining the metal layer 162 (e.g., being spaced apart from the metal layer 162.

Meanwhile, the metal layer 162 may be made of a metallic material with low reactivity to minimize or reduce the penetration of moisture into the display area AA. For example, the metal layer 162 may be configured as a double layer made of copper (Cu) and a molybdenum-titanium (Mo—Ti) alloy. However, the present specification is not limited thereto. As an example, the metal layer 162 may be configured as a single layer or multilayers. As an example, the metal layer 162 may be formed of an organic layer or an inorganic layer other than metal.

With reference to FIGS. 5 and 6, the encapsulation part EN and the substrate 110 may be disposed to be opposite to each other to be joined to each other. In this case, to minimize or reduce damage to the substrate 110 caused by the protruding portion 150b of the encapsulation substrate 150 during the joining process, the protruding portion 150b of the encapsulation substrate 150 and the groove of the spacer 160 disposed on the substrate 110 may be disposed to correspond to each other. In addition, the width t2 of the groove of the spacer 160 may be equal to the width t1 of the protruding portion of the encapsulation substrate 150 or larger than the width t1 of the protruding portion so that the protruding portion 150b of the encapsulation substrate 150 may be assembled to the groove of the spacer 160.

When the encapsulation part EN and the substrate 110 are joined, the second bonding layer 142 may adjoin the substrate 110. The second bonding layer 142 may be disposed to cover the top surface of the substrate 110, the top surface and the side surface of the display part DP, and the top surface and the side surface of the spacer 160 and protect the display part DP while fixing the substrate 110 and the encapsulation substrate 150.

Meanwhile, the protruding portion 150b of the encapsulation substrate 150 may be assembled to the groove of the spacer 160 and disposed to occupy the entire groove, without being limited thereto. Therefore, the moisture penetration may be blocked by the protruding portion 150b of the encapsulation substrate 150 even though moisture penetrates into an interface between the second bonding layer 142 and the spacer 160. In addition, because the end of the protruding portion 150b of the encapsulation substrate 150 adjoins the metal layer 162 of the spacer 160 made of a material with low reactivity, the moisture penetration through the interface between the metal layer 162 and the protruding portion 150b may be effectively blocked.

A narrow bezel is implemented in various ways so that the non-display area is minimally recognized visually by a user. However, as the bezel area decreases, a moisture penetration route to the display area also decreases, and moisture, which is introduced from the side surface of the display device, may quickly propagate to the display area. For this reason, the reliability of the display device may deteriorate.

For example, as one of the encapsulation methods for protecting the display device from outside moisture or the like, there is a method of encapsulating a light-emitting element with a surface encapsulant. The surface encapsulant may serve as a bonding layer and include a moisture adsorbent, such that the surface encapsulant may absorb moisture introduced from the outside of the display device. In this case, after the surface encapsulant is applied onto one surface of the encapsulation substrate, the encapsulation substrate may be joined to the substrate on which the transistor and the light-emitting element are disposed. When pressure is removed after the surface encapsulant disposed between the two joined substrates is cured, the display device may have a surface-encapsulated structure. In this case, the encapsulation substrate may be made of glass, plastic, metal, or the like. In particular, in case that the encapsulation substrate is made of metal, the moisture penetration may be effectively suppressed.

Meanwhile, for example, a moisture adsorbent may be further added to the surface encapsulant to improve the effect of suppressing the moisture penetration. However, in case that the surface encapsulant includes a predetermined or larger amount of moisture adsorbent, stress caused by expansion of the moisture adsorbent may increase. In case that the increased stress is transmitted to the display panel, the stress may also affect the display quality. Therefore, there is a limitation in improving the effect of suppressing the moisture penetration by adding the moisture adsorbent.

Therefore, in the display device 100 according to the aspect of the present specification, the encapsulation substrate 150 made of metal may include the base portion 150a disposed to be opposite to the substrate 110, and the protruding portions 150b protruding from the base portion 150a toward the substrate 110. In this case, the protruding portion 150b may be disposed in the non-display area NA. That is, the base portion 150a may protect the display device 100 from moisture introduced from above the display device 100. The protruding portion 150b may be disposed to be perpendicular to the substrate 110 and block moisture introduced from the side surface of the display device 100, thereby protecting the display device 100.

In this case, the spacer 160 may be disposed on the substrate 110 and absorb an impact that may occur during the process of joining the encapsulation substrate 150 and the substrate 110. The spacer 160 may be provided on the substrate 110 and disposed in the non-display area NA while corresponding to the area in which the protruding portion 150b of the encapsulation substrate 150 is disposed. In addition, the spacer 160 may include a groove structure provided in the top surface thereof. Therefore, the end of the protruding portion 150b of the encapsulation substrate 150 may not be in direct contact with the substrate 110 during the process of joining the encapsulation substrate 150 and the substrate 110. That is, the spacer 160 may include the metal layer 162 disposed on the organic pattern 161 disposed to be spaced apart from each other. In this case, the metal layer 162 may be disposed between the organic pattern 161 and adjoin the substrate 110. Therefore, the end of the protruding portion 150b of the encapsulation substrate 150 may adjoin the metal layer 162 of the spacer 160 instead of the substrate 110. Therefore, the spacer 160 may minimize or reduce an impact that may be applied to the substrate 1 10 by the protruding portion 150b of the encapsulation substrate 150.

In addition, in the display device 100 according to the aspect of the present specification, the metal layer 162 of the spacer 160 may be made of a material with low reactivity. Therefore, it is possible to effectively block the penetration of moisture through the interface between the protruding portion 150b of the encapsulation substrate 150 and the metal layer 162 of the spacer 160.

That is, in the display device 100 according to the aspect of the present specification, the encapsulation substrate 150 includes the protruding portion 150b, which may suppress the lateral moisture penetration. Further, the spacer 160 is disposed on the substrate 110, which may minimize or reduce an impact caused by the protruding portion 150b of the encapsulation substrate 150. Therefore, the reliability of the display device 100 may be improved.

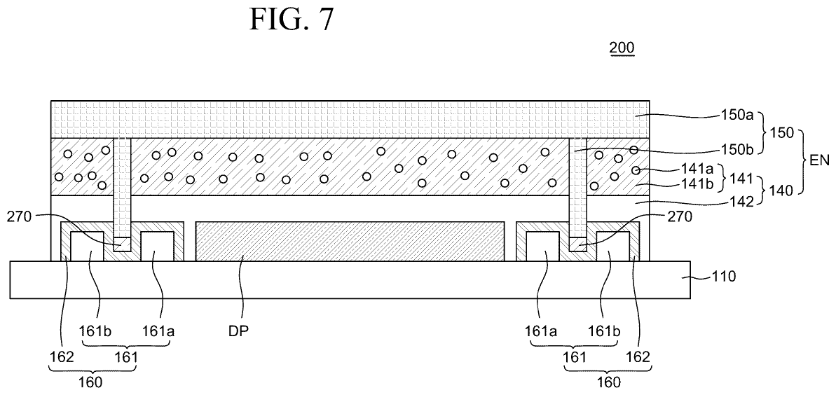

FIG. 7 is a schematic cross-sectional view according to another aspect of the present specification. A display device 200 in FIG. 7 is substantially identical in configuration to the display device 100 in FIGS. I to 6, except for the presence or absence of an auxiliary bonding layer 270. Therefore, a repeated description will be omitted.

With reference to FIG. 7, the auxiliary bonding layer 270 may be provided in the groove of the spacer 160 and disposed between the spacer 160 and the protruding portion 150b of the encapsulation substrate 150. The auxiliary bonding layer 270 may be disposed on a bottom surface of the protruding portion 150b of the encapsulation substrate 150 and more effectively fix the encapsulation substrate 150 and the substrate 110. For example, the encapsulation substrate 150 may be joined to the substrate 110 in a state in which the auxiliary bonding layer 270 is disposed on a bottom surface 150b of the protruding portion of the encapsulation substrate 150. However, the present specification is not limited thereto. As an example, the encapsulation substrate 150 may be joined to the substrate 110 in a state in which the auxiliary bonding layer 270 is disposed on a bottom surface of the groove.

Meanwhile, the auxiliary bonding layer 270 may be disposed to be spaced apart from the bonding layer 140 to block the moisture penetration route to the display area AA. However, the present specification is not limited thereto.

For example, the auxiliary bonding layer 270 may be made of the same material as the first bonding layer 141 or the second bonding layer 142. In particular, in case that the auxiliary bonding layer 270 is made of the same material as the first bonding layer 141 and includes the moisture adsorbent 141a, the auxiliary bonding layer 270 may absorb or remove moisture introduced through the interface between the spacer 160 and the auxiliary bonding layer 270 or the interface between the auxiliary bonding layer 270 and the protruding portion 150b of the encapsulation substrate 150, such that the lateral moisture penetration may be effectively suppressed. The present specification is not limited thereto. As an example, the auxiliary bonding layer 270 may be made of a different material from the first bonding layer 141. As an example, the auxiliary bonding layer 270 may be made of a different material from the first bonding layer 141, while including a moisture adsorbent the same as or different from the moisture adsorbent 141a.

That is, in the display device 200 according to another aspect of the present specification, the encapsulation substrate 150 may include the base portion 150a disposed to be opposite to the substrate 110, and the protruding portions 150b protruding from the base portion 150a toward the substrate 110. In this case, the protruding portion 150b may be disposed in the non-display area NA. That is, the base portion 150a may protect the display device 200 from moisture introduced from above the display device 200. The protruding portion 150b may be disposed to be perpendicular to the substrate 110 and protect the display device 200 from moisture introduced from the side surface of the display device 200.

In this case, the spacer 160 may be disposed on the substrate 110 and absorb an impact that may occur during the process of joining the encapsulation substrate 150 and the substrate 110. The spacer 160 may be provided on the substrate 110 and disposed in the non-display area NA while corresponding to the area in which the protruding portion 150b of the encapsulation substrate 150 is disposed. In addition, the spacer 160 may include a groove structure provided in the top surface thereof. The spacer 160 may include the metal layer 162 disposed on the organic pattern 161 disposed to be spaced apart from each other. In this case, the metal layer 162 may be disposed between the organic pattern 161 and adjoin the substrate 110. Therefore, the end of the protruding portion 150b of the encapsulation substrate 150 may adjoin the metal layer 162 of the spacer 160 instead of the substrate 110. Therefore, the spacer 160 may minimize or reduce an impact that may be applied to the substrate 110 by the protruding portion 150b of the encapsulation substrate 150.

In addition, in the display device 200 according to another aspect of the present specification, the metal layer 162 of the spacer 160 may be made of a material with low reactivity. Therefore, it is possible to effectively block the penetration of moisture through the interface between the protruding portion 150b of the encapsulation substrate 150 and the metal layer 162 of the spacer 160.

In particular, in the display device 200 according to another aspect of the present specification, the auxiliary bonding layer 270 may be additionally disposed between the protruding portion 150b of the encapsulation substrate 150 and the groove of the spacer 160. Therefore, a fixing force between the substrate 110 and the encapsulation substrate 150 may be increased, which may improve the encapsulation effect.

In addition, in the display device 200 according to another aspect of the present specification, the auxiliary bonding layer 270 may be made of the same material as the first bonding layer 141. That is, because the auxiliary bonding layer 270 includes the moisture adsorbent 141a, the auxiliary bonding layer 270 may absorb or remove moisture introduced through the interface between the auxiliary bonding layer 270 and the spacer 160 or the interface between the auxiliary bonding layer 270 and the protruding portion 150b, such that the lateral moisture penetration may be more effectively suppressed.

The exemplary aspects of the present disclosure may also be described as follows:

According to an aspect of the present disclosure, there is provided a display device. The display device includes a substrate including a display area, and a non-display area extending from the display area, an encapsulation substrate including a base portion disposed to be opposite to the substrate, and a protruding portion protruding from the base portion toward the substrate and disposed in the non-display area and a bonding layer disposed between the substrate and the encapsulation substrate and disposed in an area excluding an area in which the protruding portion is disposed.

The display device may further include a spacer disposed on the substrate in the non-display area between the protruding portion and the substrate.

The spacer has a grove disposed in a top surface of the spacer, and an end of the protruding portion may be disposed in the groove of the spacer.

The bonding layer may include a first bonding layer and a second bonding layer disposed below the first bonding layer. The first bonding layer may include a moisture adsorbent.

The first bonding layer may adjoin a bottom surface of the base portion. The second bonding layer may adjoin a top surface of the substrate.

A width of the groove of the spacer may be equal to or larger than a width of the protruding portion.

The spacer may further include a first pattern disposed on the substrate, a second pattern provided on the substrate and disposed outward of the first pattern and a cover layer disposed to cover a surface of the first pattern and a surface of the second organic pattern.

The cover layer may be disposed between the first pattern and the second pattern and adjoins the substrate.

The end of the protruding portion may be disposed in the groove of the spacer and adjoins the cover layer.

The cover layer may be a metal layer.

The metal layer may include copper (Cu) and molybdenum-titanium (Mo—Ti).

The first pattern, the second pattern, and the cover layer may be disposed to surround the display area.

The display device may further include an auxiliary bonding layer disposed in the groove of the spacer and disposed between the protruding portion and the spacer.

The bonding layer may include a first bonding layer and a second bonding layer disposed below the first bonding layer. The auxiliary bonding layer may be made of the same material as one of the first bonding layer and the second bonding layer.

The first bonding layer may include a moisture adsorbent.

The auxiliary bonding layer may include a moisture adsorbent.

The first pattern and the second pattern may be organic patterns.

The first pattern and the second pattern may be made of the same material as a planarization layer configured to planarize an upper portion of a pixel circuit or a bank configured to define a light-emitting area.

The protruding portion may be disposed to be perpendicular to the substrate.

The protruding portion may be disposed to overlap a display part disposed on the substrate, in a lateral direction.

The protruding portion may be disposed to surround the display area.

The bonding layer may adjoin a bottom surface of the base portion, a top surface of the substrate, a top surface and a side surface of a display part disposed on the substrate and a side surface of the protruding portion.

Although the exemplary aspects of the present disclosure have been described in detail with reference to the accompanying drawings, the present disclosure is not limited thereto and may be embodied in many different forms without departing from the technical concept of the present disclosure. Therefore, the exemplary aspects of the present disclosure are provided for illustrative purposes only but not intended to limit the technical concept of the present disclosure. The scope of the technical concept of the present disclosure is not limited thereto. Therefore, it should be understood that the above-described exemplary aspects are illustrative in all aspects and do not limit the present disclosure. All the technical concepts in the equivalent scope of the present disclosure should be construed as falling within the scope of the present disclosure.

What is claimed is:

1. A display device comprising:
a substrate including a display area, and a non-display area extending from the display area;
an encapsulation substrate including a base portion disposed to be opposite to the substrate, and a protruding portion protruding from the base portion toward the substrate and disposed in the non-display area; and
a bonding layer disposed between the substrate and the encapsulation substrate and disposed in an area excluding an area in which the protruding portion is disposed.

2. The display device of claim 1, further comprising a spacer disposed on the substrate in the non-display area between the protruding portion and the substrate.

3. The display device of claim 2, wherein the spacer has a groove disposed in a top surface of the spacer, and an end of the protruding portion is disposed in the groove of the spacer.

4. The display device of claim 1, wherein the bonding layer comprises:
a first bonding layer; and
a second bonding layer disposed below the first bonding layer,
wherein the first bonding layer includes a moisture adsorbent.

5. The display device of claim 4, wherein the first bonding layer adjoins a bottom surface of the base portion, and
wherein the second bonding layer adjoins a top surface of the substrate.

6. The display device of claim 3, wherein a width of the groove of the spacer is equal to or larger than a width of the protruding portion.

7. The display device of claim 3, wherein the spacer further comprises:
a first pattern disposed on the substrate;
a second pattern provided on the substrate and disposed outward of the first pattern; and
a cover layer disposed to cover a surface of the first pattern and a surface of the second pattern.

8. The display device of claim 7, wherein the cover layer is disposed between the first pattern and the second pattern and adjoins the substrate.

9. The display device of claim 7, wherein an end of the protruding portion is disposed in the groove of the spacer and adjoins the cover layer.

10. The display device of claim 7, wherein the cover layer is a metal layer.

11. The display device of claim 10, wherein the metal layer includes copper (Cu) and molybdenum-titanium (Mo—Ti).

12. The display device of claim 7, wherein the first pattern, the second pattern, and the cover layer are disposed to surround the display area.

13. The display device of claim 3, further comprising an auxiliary bonding layer disposed in the groove of the spacer and disposed between the protruding portion and the spacer.

14. The display device of claim 13, wherein the bonding layer comprises:
a first bonding layer; and
a second bonding layer disposed below the first bonding layer, and
wherein the auxiliary bonding layer is made of the same material as one of the first bonding layer and the second bonding layer.

15. The display device of claim 14, wherein the first bonding layer includes a moisture adsorbent.

16. The display device of claim 13, wherein the auxiliary bonding layer includes a moisture adsorbent.

17. The display device of claim 7, wherein the first pattern and the second pattern are organic patterns.

18. The display device of claim 7, wherein the first pattern and the second pattern are made of the same material as a planarization layer configured to planarize an upper portion of a pixel circuit or a bank configured to define a light-emitting area.

19. The display device of claim 1, wherein the protruding portion is disposed to be perpendicular to the substrate.

20. The display device of claim 1, wherein the protruding portion is disposed to overlap a display part disposed on the substrate, in a lateral direction.

21. The display device of claim 1, wherein the protruding portion is disposed to surround the display area.

22. The display device of claim 1, wherein the bonding layer adjoins a bottom surface of the base portion, a top surface of the substrate, a top surface and a side surface of a display part disposed on the substrate and a side surface of the protruding portion.
